(19) United States
(12) Patent Application Publication
(10) Pub. No.: US 2009/0236136 A1
(43) Pub. Date: Sep. 24, 2009

(54) Printed circuit board assembly

(75) Inventor: Peter Chiang, Jung-He City (TW)

Correspondence Address: VISTA IP LAW GROUP LLP, 12930 Saratoga Avenue, Suite D-2, Saratoga, CA, 95070, US

(73) Assignee: Micro-Star International Co., Ltd., Jung-He City (TW)

(21) Appl. No.: 12/228,706

(22) Filed: Aug. 15, 2008

(30) Foreign Application Priority Data
Feb. 27, 2008 (TW) 097106827

(51) Int. Cl. H05K 1/11; H05K 3/34

(52) U.S. Cl. 174/261; 29/840

(57) ABSTRACT

A printed circuit board assembly includes: a substrate; an soldermask formed on the substrate and formed with a recess; a solder pad having a first end portion received in the recess and formed on the portion of the substrate, and a second end portion extending from the first end portion; and a solder paste having a first end portion formed on the first end portion of the solder pad, and a second end portion extending from the first end portion of the solder paste and formed on a portion of the soldermask, which is formed on the second end portion of the solder pad.

### CROSS-REFERENCE TO RELATED APPLICATION

This application claims priority of Taiwanese application no. 097106827, filed on Feb. 27, 2008.

### BACKGROUND OF THE INVENTION

1. Field of the Invention

This invention relates to a printed circuit board assembly, more particularly to a printed circuit board assembly including a solder paste formed on a portion of a soldermask, which is formed on a portion of a solder pad.

2. Description of the Related Art

Electronic components can be classified into two types: plated through-hole components and surface mount components. The plated through-hole components usually have pins for extending respectively into holes in a printed circuit board so that the pins are soldered to a back side of the printed circuit board after passing through a solder oven. The surface mount components have end caps for mounting directly on a surface of a printed circuit board.

FIG. 1 illustrates a conventional printed circuit board 9 including a substrate 93, a soldermask 94 formed on the substrate 93 and formed with a recess 941, a pair of solder pads 92, which are received in the recess 941, a pair of conductive traces 95 each extending from a respective one of the solder pads 92 and each having a first end portion 951 covered by the soldermask 94 and a second end portion 952 that extends between the first end portion 951 of the conductive trace 95 and the respective solder pad 92, and that is exposed to the atmosphere, and a lead-free solder paste 91 applied on the solder pads 92 for connecting leads 961 of an electronic component 96 thereto.

During soldering, the leads 961 of the electronic component 96 are attached to the lead-free solder paste 91 on the solder pads 92 of the printed circuit board 9, and the assembly is subsequently disposed in a reflow-soldering oven so as to conduct soldering. Since the lead-free solder paste 91 has a high surface tension, the lead-free solder paste 91 contracts so as to minimize the surface area thereof, which results in undesired exposure of a portion of each of the solder pads 92 to the atmosphere after soldering, which, in turn, results in problems, such as open-circuit in the solder joint, naked copper, cold joint, and generation of ineffective soldering area for the solder pads 92. In addition, the joint area between each solder pad 92 and the respective conductive trace 95 tends to corrode after a period of use.

Taiwanese Patent No. 249213 discloses a printed circuit board including a pair of solder pads formed on a substrate, a soldermask formed on the substrate and a portion of each solder pad, and a lead-free solder paste applied on the remainder of each solder pad by screen printing techniques. However, the problems of generation of ineffective soldering area and cold joint are still present.

### SUMMARY OF THE INVENTION

Therefore, one object of the present invention is to provide a printed circuit board assembly that can overcome the aforesaid drawbacks associated with the prior art.

Another object of this invention is to provide a method for making the printed circuit board assembly.

According to one aspect of the present invention, the printed circuit board assembly comprises: a substrate; a soldermask formed on the substrate and formed with a recess to expose a pad-forming portion of the substrate; a solder pad having a first end portion received in the recess and formed on the pad-forming portion of the substrate, and a second end portion extending from the first end portion; and a solder paste having a first end portion formed on the first end portion of the solder pad, and a second end portion extending from the first end portion of the solder paste and formed on a portion of the soldermask, which is formed on the second end portion of the solder pad.

According to another aspect of this invention, there is provided a method for making the printed circuit board assembly, comprising: (a) forming solder pads on a substrate; (b) covering the substrate and a portion of each of the solder pads using a soldermask; (c) applying a solder paste on a portion of the soldermask, which is formed on the portion of each of the solder pads, and the remainder of each of the solder pads; (d) attaching leads of an electronic component to the solder paste; and (e) reflowing the solder paste on the solder pads.

### BRIEF DESCRIPTION OF THE DRAWINGS

Other features and advantages of the present invention will become apparent in the following detailed description of the preferred embodiments of this invention, with reference to the accompanying drawings, in which:

FIG. 1 is a perspective view of a conventional printed circuit board;

FIG. 2 is a perspective view of the first preferred embodiment of a printed circuit board assembly according to this invention;

FIG. 3 is a perspective view of the second preferred embodiment of a printed circuit board assembly according to this invention;

FIGS. 4 to 7 are perspective views to illustrate consecutive steps of a method for making the printed circuit board assembly according to this invention; and

FIGS. 8 to 11 are fragmentary sectional views of FIGS. 4 to 7, respectively.

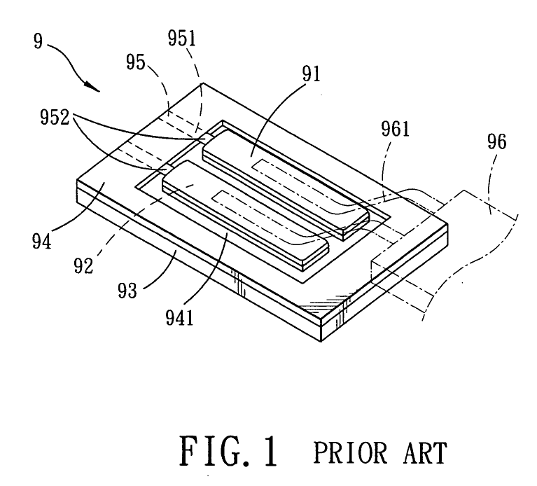

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

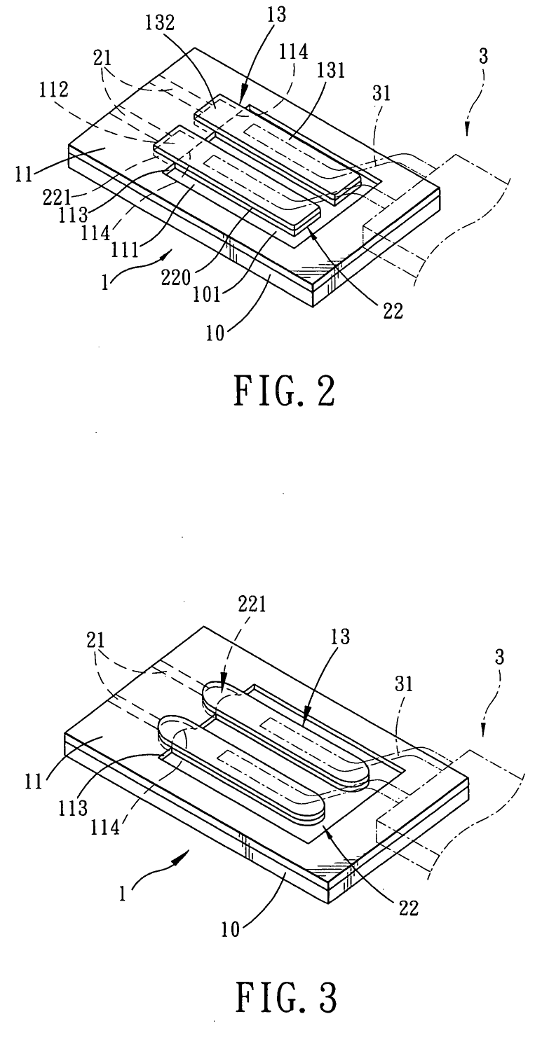

FIG. 2 illustrates the first preferred embodiment of a printed circuit board assembly 1 according to this invention. The printed circuit board assembly 1 includes: a substrate 10; a soldermask 11 formed on the substrate 10 and formed with a recess 111 so as to expose a pad-forming portion 101 of the substrate 10; a pair of solder pads 22 each having a first end portion 220 received in the recess 111 of the soldermask 11 and formed on the pad-forming portion 101 of the substrate 10, and a second end portion 221 extending from the first end portion 220 of the solder pad 22; and a lead-free solder paste 13 having a first end portion 131 formed on the first end portion 220 of each of the solder pads 22, and a second end portion 132 extending from the first end portion 131 of the lead-free solder paste 13 and formed on a portion 112 of the soldermask 11, which is formed on the second end portion 221 of the solder pad 22.

In this embodiment, the printed circuit board assembly 1 further includes a pair of conductive traces 21 each of which is formed on the substrate 10, covered by the soldermask 11, and connected to the second end portion 221 of a respective one of the solder pads 22.

In this embodiment, the recess 111 of the soldermask 11 has a peripheral edge 113, which has a segment 114 dividing each of the solder pads 22 into the first and second end portions 220, 221. The segment 114 is linear in shape.

Preferably, the first and second end portions 220, 221 of each of the solder pads 22 are opposite to each other in a direction along the length of the solder pad 22. The second end portion 221 of each of the solder pads 22 has a length along the direction ranging from 4 to 6 mil.

Preferably, each of the conductive traces 21 and the solder pads 22 is made from copper.

FIG. 3 illustrates the second preferred embodiment of the printed circuit board assembly 1 according to the present invention. The second preferred embodiment differs from the previous embodiment in that the segment 114 is curved in shape.

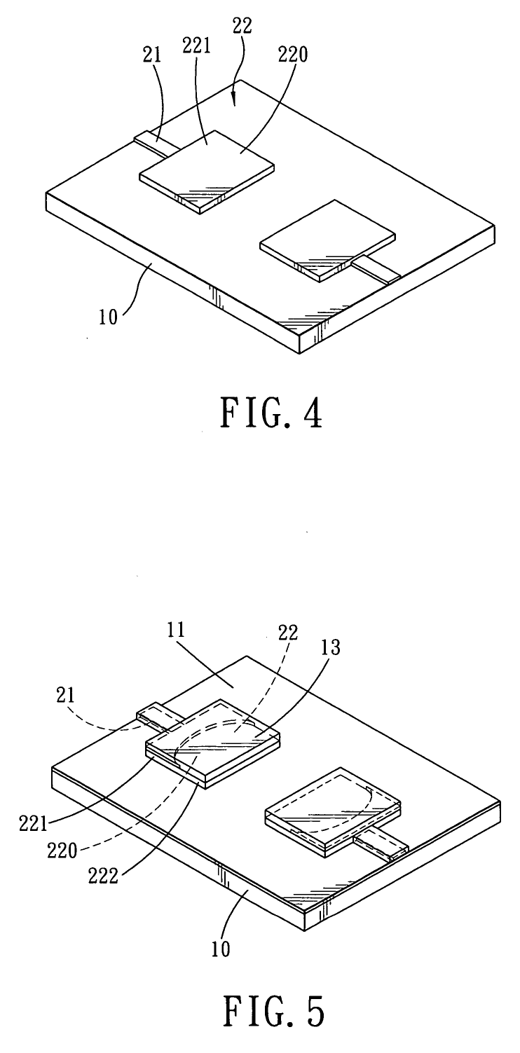

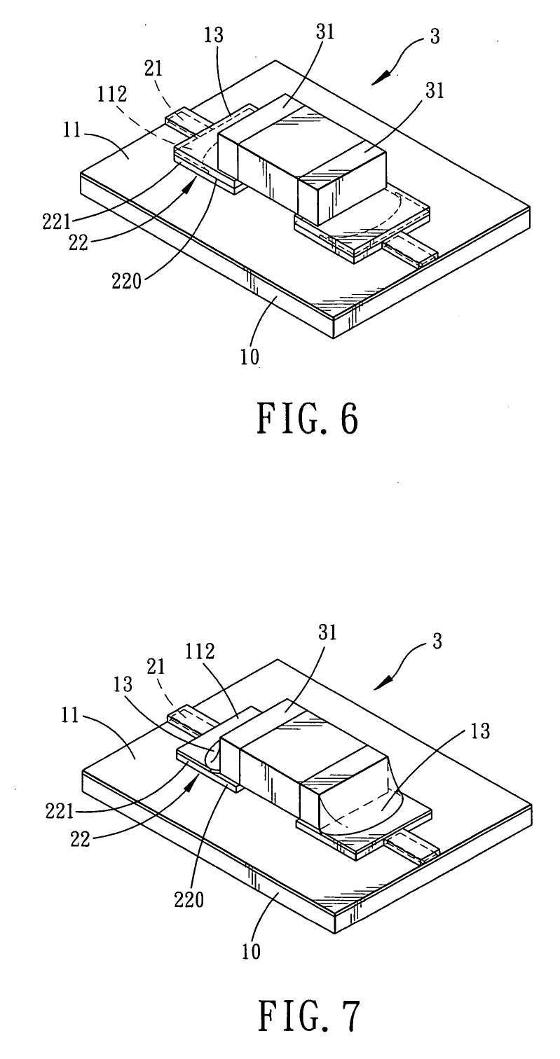

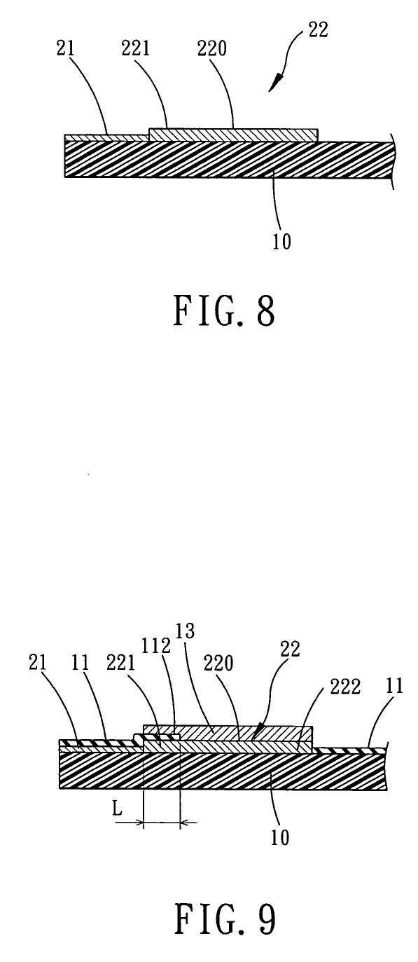

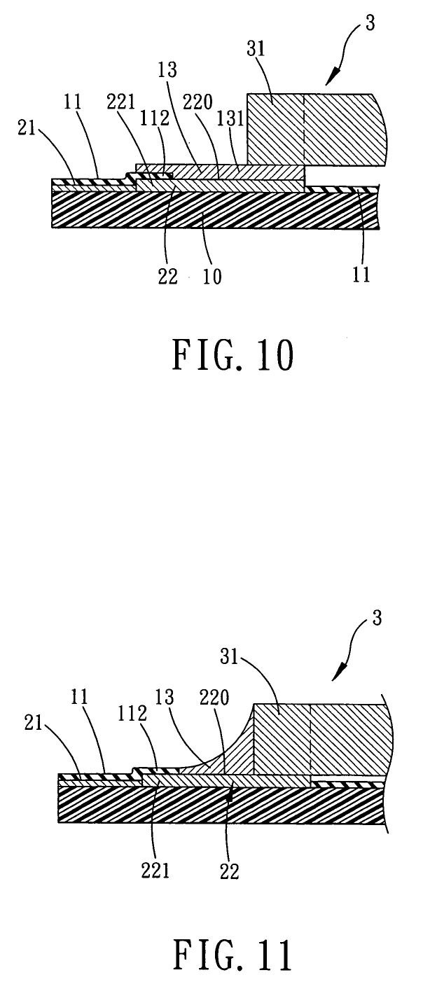

This invention also provides a method for making the printed circuit board assembly 1 with at least one electronic component 3 soldered thereto. The method includes: (a) forming the solder pads 22 on the substrate 10 (see FIGS. 4 and 8); (b) covering the substrate 10 and the second end portion 221 of each of the solder pads 22 using the soldermask 11 (see FIGS. 5 and 9); (c) applying the lead-free solder paste 13 on the portion 112 of the soldermask 11 (see FIGS. 5 and 9), which is formed on the second end portion 221 of each of the solder pads 22, and on the remainder, i.e., the first end portion 220, of the solder pads 22; (d) attaching leads 31 of the electronic component 3 to the lead-free solder paste 13 (see FIGS. 6 and 10); and (e) reflowing the lead-free solder paste 13 on the solder pads 22(see FIGS. 7 and 11).

Preferably, the method further includes forming the conductive traces 21 on the substrate 10, each of which is connected to the second end portion 221 of the respective solder pads 22 and is covered by the soldermask 11.

Note that the lead-free solder paste 13 contracts toward the leads 31 of the electronic component 3 during reflowing due to its surface tension. By virtue of forming the lead-free solder paste 13 on the portion 112 of the soldermask 11, the lead-free solder paste 13 can completely cover the first end portion 220 of each of the solder pads 22 after reflowing so as to prevent generation of the ineffective solder area or occurrence of naked copper and cold joint for the solder pads 22.

By forming the lead-free solder paste 13 on the portion 112 of the soldermask 11, which is formed on the second end portion 221 of the solder pad 22 of the printed circuit board assembly 1 of this invention, the aforesaid drawbacks associated with the prior art can be eliminated.

With the invention thus explained, it is apparent that various modifications and variations can be made without departing from the spirit of the present invention. It is therefore intended that the invention be limited only as recited in the appended claims.

What is claimed is:

1. A printed circuit board assembly comprising:
a substrate;
a soldermask formed on said substrate and formed with a recess to expose a pad-forming portion of said substrate;
a solder pad having a first end portion received in said recess and formed on said pad-forming portion of said substrate, and a second end portion extending from said first end portion; and
a solder paste having a first end portion formed on said first end portion of said solder pad, and a second end portion extending from said first end portion of said solder paste and formed on a portion of said soldermask, which is formed on said second end portion of said solder pad.

2. The printed circuit board assembly of claim 1, further comprising a conductive trace formed on said substrate, covered by said soldermask, and connected to said second end portion of said solder pad.

3. The printed circuit board assembly of claim 1, wherein said recess of said soldermask has a peripheral edge, which has a segment dividing said solder pad into said first and second end portions, said segment being linear in shape.

4. The printed circuit board assembly of claim 1, wherein said recess of said soldermask has a peripheral edge, which has a segment dividing said solder pad into said first and second end portions, said segment being curved in shape.

5. The printed circuit board assembly of claim 1, wherein said first and second end portions of said solder pad are opposite to each other in a direction along the length of said solder pad, said second end portion of said solder pad having a length along the direction ranging from 4 to 6 mil.

6. A method for making a printed circuit board assembly with at least one electronic component soldered thereto, comprising:
(a) forming solder pads on a substrate;
(b) covering the substrate and a portion of each of the solder pads using an soldermask;
(c) applying a solder paste on a portion of the soldermask, which is formed on the portion of each of the solder pads, and the remainder of each of the solder pads;
(d) attaching leads of the electronic component to the solder paste; and
(e) reflowing the solder paste on the solder pads.
